(19) United States
(12) Patent Application Publication
(10) Pub. No.: US 2025/0285990 A1
(43) Pub. Date: Sep. 11, 2025

(54) SHIELDING PARTICLES COATED WITH ELECTRICAL INSULATION

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 18/680,129

(22) Filed: May 31, 2024

Related U.S. Application Data
(60) Provisional application No. 63/563,243, filed on Mar. 8, 2024.

(51) Int. Cl. H01L 23/552; C08K 9/02; H01L 21/56; H01L 23/29; H01L 23/31

(52) U.S. Cl. CPC H01L 23/552; C08K 9/02; H01L 21/565; H01L 23/291; H01L 23/296; H01L 23/3135

(57) ABSTRACT

Methods to coat shielding particles with an electrically insulating coating, disperse the coated shielding particles in an base material to form a mold structure; and position the mold structure proximate a die of an integrated circuit package to shield the die from radiation. Devices comprising: a die; and a mold structure proximate the die, the mold structure comprising: an base material; and shielding particles comprising an electrically insulating coating, wherein the shielding particles are dispersed in the base material.

### PRIORITY STATEMENT

This application claims priority to U.S. Provisional Patent Application No. 63/563,243, filed Mar. 8, 2024, the contents of which are hereby incorporated in their entirety.

### TECHNICAL FIELD

The present disclosure relates to radiation shielded die packages, in particular, die packages comprising a shielding compound having shielding particles coated with an electrical insulation coating and dispersed in a base material.

### BACKGROUND

There is a growing need for Radiation Tolerant (RT) semiconductors for applications like avionics as well as Low Earth Orbit (LEO) satellites. Normally to create these types of products, either a specific expensive manufacturing fabrication process is used, or the products are placed in expensive ceramic packages.

There is a need for RT semiconductors with reduced cost.

### SUMMARY

Most semiconductors are over-molded with a compound comprising an epoxy base material and over 80% silicon dioxide (SiO₂) filler particles for structural stability. An aspect replaces, at least in part, these SiO₂ filler particles with a radiation blocking material (such as an Ag—Sn alloy) coated with SiO₂, to achieve a level of radiation blocking without needing to use a ceramic package or alter the fabrication process.

Aspects provide a method comprising: coating shielding particles with an electrically insulating coating; dispersing the coated shielding particles in a base material to form a mold structure; and positioning the mold structure proximate a die of an integrated circuit package to shield the die from radiation.

According to an aspect, this is provided a method as described above, wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO).

According to an aspect, this is provided a method as described above, wherein the shielding particles comprise a material from at least one of the Cobalt oxide family, the Nickle oxide family. the Neodymium oxide family, and the Iron oxide family.

According to an aspect, this is provided a method as described above, wherein the electrically insulating coating comprises silicon dioxide (SiO₂).

According to an aspect, this is provided a method as described above, wherein the base material comprises polymer, silicone, polyurethane, chloroprene, butyl, polybutadiene. neoprene. natural rubber, isoprene, resin, or epoxy.

According to an aspect, this is provided a method as described above, comprising dispersing a plurality of silicon dioxide (SiO₂) filler particles in the base material to form the mold structure.

According to an aspect, this is provided a method as described above, wherein dispersed particles comprise 50% to 95% shielding particles and 50% to 5% silicon dioxide filler particles.

According to an aspect, this is provided a method as described above, wherein positioning the mold structure proximate the die comprises the mold structure at least partially encapsulating the die.

According to an aspect, this is provided a method as described above, wherein positioning the mold structure proximate the die comprises comprising positioning first and second shielding layers, wherein the first and second shielding layers comprise different concentrations of the coated shielding particles.

According to an aspect, there is provided a device comprising: a die; and a mold structure proximate the die, the mold structure comprising: a base material; and shielding particles comprising an electrically insulating coating, wherein the shielding are dispersed in the base material.

An aspect provides a device as described above, wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO).

An aspect provides a device as described above, wherein the shielding particles comprise a material from at least one of the Cobalt oxide family, the Nickle oxide family, the Neodymium oxide family, and the Iron oxide family.

An aspect provides a device as described above, wherein the electrically insulating coating comprises silicon dioxide (SiO₂).

An aspect provides a device as described above, wherein the base material comprises a material selected from polymer, silicone, polyurethane, chloroprene, butyl, polybutadiene, neoprene, natural rubber, isoprene, resin, and epoxy.

An aspect provides a device as described above, wherein the mold structure comprises silicon dioxide (SiO₂) filler particles.

An aspect provides a device as described above, wherein particles in the mold structure comprise 50% to 95% shielding particles and 50% to 5% silicon dioxide (SiO₂) filler particles.

An aspect provides a device as described above, comprising an encapsulate at least partially encapsulating the die, wherein the mold structure is proximate the encapsulate.

An aspect provides a device as described above, wherein the mold structure comprises first and second shielding layers, wherein the first and second shielding layers comprise different concentrations of shielding particles.

According to an aspect, there is provided an integrated circuit package comprising: a die carrier; a die mounted on the die carrier; and a mold structure proximate the die, the mold structure comprising: a base material; shielding particles comprising an electrically insulating coating, the shielding particles dispersed in the base material; and silicon dioxide (SiO₂) filler particles dispersed in the base material.

An aspect provides a system as described above, wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO), wherein the electrically insulating coating comprises silicon dioxide (SiO₂), wherein the base material comprises polymer, silicone, polyurethane. chloroprene, butyl, polybutadiene, neoprene, natural rubber, isoprene, resin, or epoxy, and wherein particles in the mold structure comprises 50% to 95% shielding particles and 50% to 5% silicon dioxide (SiO₂) filler particles.

### BRIEF DESCRIPTION OF THE DRAWINGS

The figures illustrate examples of semiconductors that are over-molded with epoxy a radiation blocking material (such as an Ag—Sn alloy) coated with SiO₂, to achieve a level of radiation blocking without needing to use a ceramic package or alter the fabrication process.

FIG. 1 is a cross-sectional side view showing an example integrated circuit package including a die mounted on a die carrier, and a mold structure (e.g., a mold encapsulation) at least partially encapsulating the mounted die.

FIG. 2 shows a cross-sectional side view of an example integrated circuit package having a die on a die carrier and having an encapsulate that encapsulates the die. and a mold structure that covers the encapsulate to shield the die from radiation.

FIG. 3 shows a cross-sectional side view of an example integrated circuit package having a die on a die carrier and having a mold structure encapsulating the die, wherein the mold structure comprises layers.

FIG. 4 is an SEM image of a shielding compound with shielding particles coated with an electrical insulator (such as SiO₂), wherein the shielding particles are sphere and colloid particles of various sizes.

FIG. 5 is a phase diagram showing alloys like Ag—Sn.

FIG. 6 is a cross-sectional side view showing an integrated circuit package including a die mounted on a die carrier, and a mold structure at least partially encapsulating the mounted die, wherein the mold structure has a shielding compound with shielding particles coated with an electrical insulator and filler particles dispersed in a base material.

FIG. 7 is a flow chart of a method of manufacturing a die package with a shielding mold structure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a shielding compound to encapsulate dies in packages. The shielding compound includes shielding particles, which are coated to make them electrically nonconductive. The coated shielding particles are dispersed in a base material, for example a polymer such as an epoxy resin.

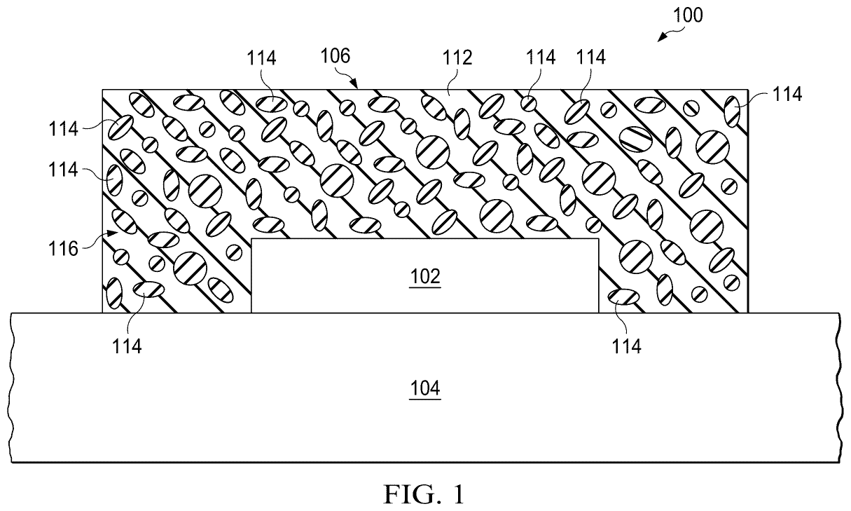

FIG. 1 is a cross-sectional side view showing an example integrated circuit package 100 including a die 102 mounted on a die carrier 104, and a mold structure 106 (e.g., a mold encapsulation) at least partially encapsulating the mounted die 102. The mold structure 106 may be proximate the die 102.

The die 102 may comprise any type of die, chip (e.g., silicon substrate having an integrated circuit formed thereon), or other integrated circuit device (e.g., including analog devices, digital devices, or a mixture of analog and digital devices) that generates or outputs heat. For example, the die 102 may comprise a microprocessor (e.g., a central processing unit (CPU) chip), a microcontroller (MCU), an application specific IC (ASIC), a graphics processing unit (GPU), a digital signal processor (DSP), an A/D converter or D/A converter, or memory (e.g., Flash memory, random access memory (RAM), read only memory (ROM), e.g., electrically erasable programmable read-only memory (EEPROM), or other memory), or a system-on-chip (SoC) device.

The die carrier 104 may comprise any structure on which the die 102 may be mounted, for example a printed circuit board (PCB), a lead frame, an interposer, a beat sink, or another die. The die 102 may be mounted on the die carrier 104 in any suitable manner, for example solder mounting, adhesive bonding (e.g., using an epoxy), flip-chip bonding, or eutectic bonding.

As shown in FIG. 1, in some examples mold structure 106 may comprise a shielding compound 112 includes shielding particles 114 dispersed in, or otherwise combined, in a base material 116, which base material 116 may be, for example, a polymer such as an epoxy resin or a polymer resin. In some examples, the shielding compound 112 includes a mixture of shielding particles 114, filler particles comprising silicon dioxide (SiO₂) particles, and a base material 116 comprising an epoxy resin. The mold structure 106 may be proximate the die 102 to shield the die from radiation.

As used herein, a “compound” may refer to one element or substance, or a mixture or other combination of multiple elements or substances. The term particles, as used herein, refers to a particle having a maximum dimension between 1 nanometer and 1000 micrometers, and may be spherical, or colloidal shaped, without limitation. Particles may have a maximum dimension between 1 and 300 micrometers, or 50-80 micrometers. Shielding particles and filler particles are described below.

In some examples the shielding particles 114 comprise at least one of gold-tin, silver-tin, tungsten, antimony, bismuth, and any heavy metal, without limitation. Heavy metals include metal with high density (for example 5 g/cm³), high atomic weights (for example greater than 63.5 gmol-1), or atomic numbers greater than 20, such as for example. boron nitride (BN), bismuth (Bi), bismuth oxide (Bi₂O₃), tantalum nitride (TaN), tungsten nitride (W₃N₂), tin oxide (SnO₂), copper (I) oxide (Cu₂O) (i.e., cuprous oxide), or copper (ID) oxide (CuO) (i.e., cupric oxide), antimony (Sb), tin (Sn), tungsten (W) particles, without limitation, wherein the heavy metal particles may be coated or encapsulated with an electrically nonconductive material, such as silicon dioxide (SiO₂). The shielding particles 114 are coated or encapsulated with an electrically nonconductive material, such as silicon dioxide (SiO₂) (also called silica). The shielding particles 114 may be coated with an electrically nonconductive material to reduce the possibility of an electrical conduction path that could short pins of an integrated circuit package together.

In some examples, the shielding particles 114 are dispersed in, or otherwise combined with, the base material 116. The base material 116 may comprise, for example, an elastomer (e.g., silicone, polyurethane, chloroprene, butyl, polybutadiene, neoprene, natural rubber or isoprene), a thermoset (e.g., thermoset resin), or other molding compound, which may be supplied in the form of pellets, liquids, or powders, for example, In some examples the shielding particles 114 may shield the die 102 from ionizing radiation, magnetic fields, or a combination of ionizing radiation and magnetic fields. Shielding particles 114 to shield from magnetic fields may comprise material from the Cobalt oxide family, the Nickle oxide family, the Neodymium oxide family and the Iron oxide family. The shielding particles 114 may comprise a material from at least one of the Cobalt oxide family, the Nickle oxide family, the Neodymium oxide family, and the Iron oxide family. Shielding particles 114 to shield from ionizing radiation may include mu-metal or hematite (Fe₂O₃) particles, for example. Thus, shielding particles 114 need not be uniform, and may comprise a plurality of different types of shielding particles.

The shielding particles 114 may be coated or encapsulated with an electrically nonconductive material, such as silicon dioxide (SiO₂), by a SOL-GEL process or a spin-on-glass process.

The coated or encapsulated shielding particles 114 may be dispersed in or otherwise combined with a base material 116 to produce the shielding compound 112. In some examples a surfactant 113 may (optionally) be added to enhance or expedite the dispersing of the shielding particles 114 in the base material 116. The shielding particles 114 (with or without surfactant 113) may be mixed or combined with the base material 116 in any suitable manner, e.g., using an agitation or ultrasonic vibration process.

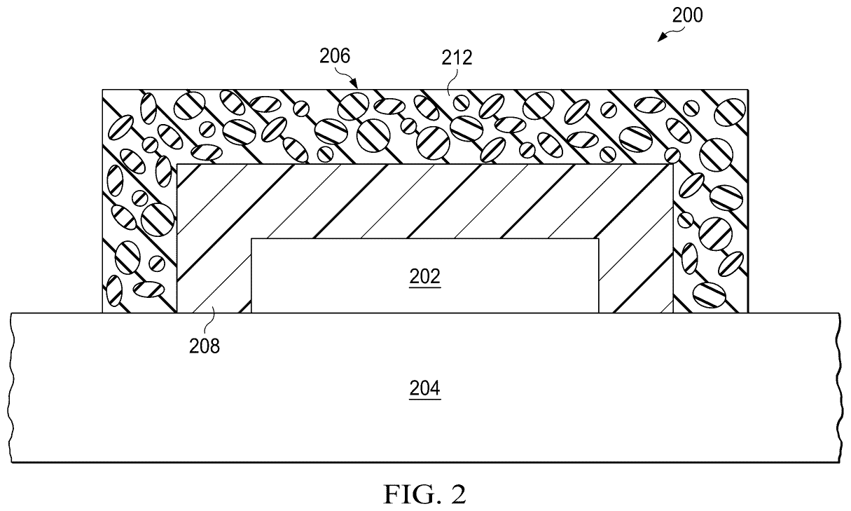

FIG. 2 shows a cross-sectional side view of a package 200 having a die 202 on a die carrier 204. An encapsulate 208 encapsulates the die 202 and comprises a material that may not shield the die 202 from radiation. A mold structure 206, comprising shielding compound 212 covers the encapsulate 208 to shield the die 202 from radiation. The illustrated example shows shielding compound 212 formed over encapsulate 208. Shielding compound 212 is similar in all respects to shielding compound 112 described above. The mold structure 206 may be proximate the die 202 to shield the die 202 from radiation.

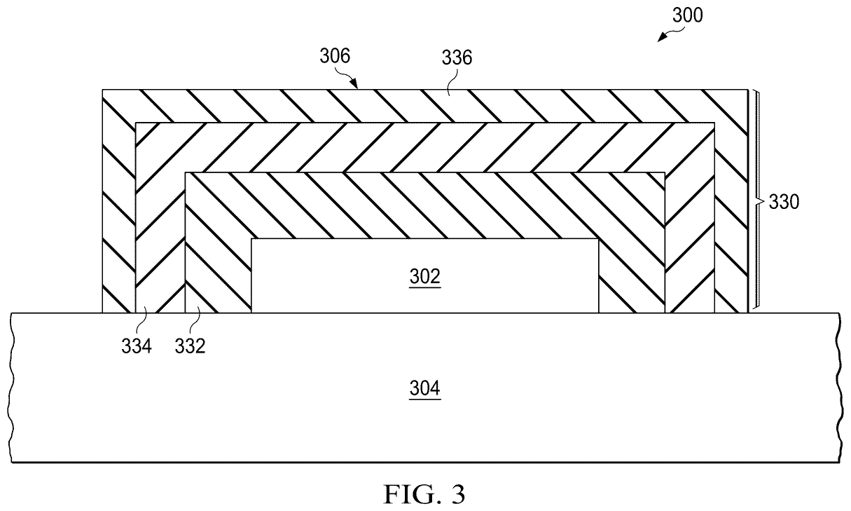

FIG. 3 shows a cross-sectional side view of a package 300 having a die 302 on a die carrier 304 with a mold structure 306 comprising three shielding layers 330. Other examples, not shown, include a single shielding layer, two shielding layers, or three, or more, shielding layers. Respective shielding layer(s) may include shielding particles dispersed in or otherwise combined with a base material. For example, respective shielding layer(s) may include shielding particles to shield the die 302 from ionizing radiation, magnetic fields, or a combination of ionizing radiation and magnetic fields, e.g., as discussed above regarding shielding compound 112, with reference to FIG. 1. The mold structure 306 may be proximate the die 302 to shield the die 302.

In examples with multiple shielding layers, different shielding layers 330 may include different types or different concentrations of shielding particles. For example, referring to the example shown in FIG. 3, shielding layer 332 may comprise magnetic shielding particles (e.g., to shield die 302 from magnetic fields) and shielding layer 334 may comprise shielding particles (e.g., to shield die 302 from ionic radiation). As another example, shielding layers 332, 334, and 336 may comprise the same type of particles (e.g., magnetic shielding particles or shielding particles) but with a respective different concentration of particles, to thereby define a shielding gradient along a direction toward or away from the die 302. For example, the shielding layers 332. 334, and 336 may provide an increasing degree of shielding in a direction toward the die 302 (e.g., wherein the shielding layer 332, which may be termed inner shielding layer 332, may provide a greater degree of shielding than shielding layer 336, which may be termed outer shielding layer 336). While three shielding layers 330 are shown in FIG. 3, any number of shielding layers may be used, without limitation, and individual layers may have any ratio of shielding particles to filler particles, without limitation. The shielding particles of the respective ones of shielding layers 330, may be coated or encapsulated with an electrically nonconductive material, such as silicon dioxide (SiO₂).

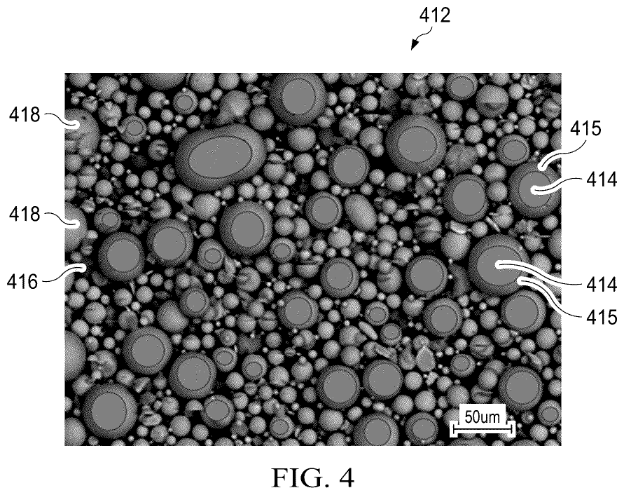

FIG. 4 is an scanning electron microscope (SEM) of a shielding compound 412 with shielding particles 414 dispersed in a base material 416. The shielding particles 414 are shown in cross-section to show that they are coated with an electrical insulator 415 (such as silicon dioxide (SiO₂)), wherein the shielding particles 414 are sphere and colloid particles of various sizes. Filler particles 418 may also be dispersed in the shielding compound 412. The filler particles 418 may thicken or otherwise enhance the structural integrity of the base material 416.

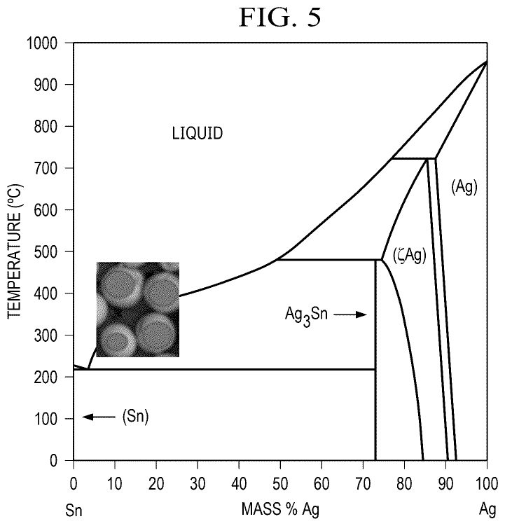

FIG. 5 is a phase diagram showing alloys like Ag—Sn allow for dialing in the radiation blocking ability while being able to hold up to processing temperatures and the mission profile of the end device. Sn has more effective radiation blocking properties than Ag. However, Sn has a relatively low melting point and may not hold up to processing temperatures by itself. By increasing the % of Ag in the alloy with Sn, the melting point increases. In some aspects, a high percentage of Sn compared to Ag may be used so the alloy will effectively block radiation without melting during package processing.

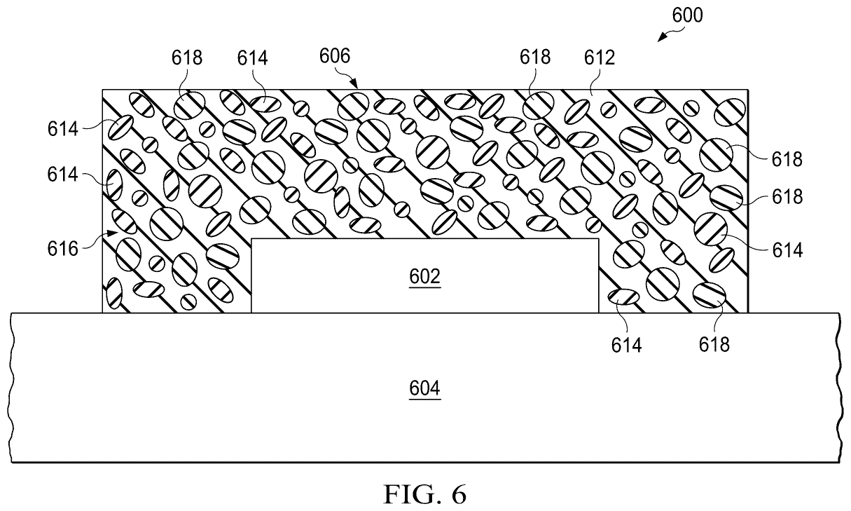

FIG. 6 is a cross-sectional side view showing an example integrated circuit package 600 including a die 602 mounted on a die carrier 604, and a mold structure 606 (e.g., a mold encapsulation) at least partially encapsulating the mounted die 602. As shown in FIG. 6, the mold structure 606 comprises a shielding compound 612, which includes shielding particles 614 dispersed in a base material 616, for example a polymer such as an epoxy resin. The shielding compound 612 also includes filler particles 618 (e.g., in the form of fumed silicon dioxide (SiO₂) or colloidal silicon dioxide (SiO₂)) to thicken or otherwise enhance the structural integrity of the base material 616 (e.g., epoxy). Thus, the shielding compound 612 may include shielding particles 614 and filler particles 618 dispersed in, or otherwise combined with, base material 616. In one example, the particles may comprise 90%-95% shielding particles 614 and 10%-5% filler particles in the shielding compound 612. In another example, particles may comprise 50%-95% shielding particles 114 and 50%-5% filler particles 618 in the shielding compound 612.

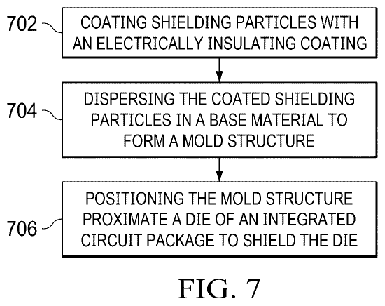

FIG. 7 shows a flow chart of a method. Shielding particles are coated 702 with an electrically insulating coating. The coated shielding particles are dispersed 704 in a base material to form a mold structure. The mold structure is positioned 706 proximate a die of an integrated circuit package to shield the die from ionic radiation.

Although examples have been described above, other variations and examples may be made from this disclosure without departing from the spirit and scope of these disclosed examples.

1. A method comprising:
coating shielding particles with an electrically insulating coating;
dispersing the coated shielding particles in a base material to form a mold structure; and
positioning the mold structure proximate a die of an integrated circuit package to shield the die.

2. The method as in claim 1, wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO).

3. The method as in claim 1, wherein the shielding particles comprise a material from at least one of the Cobalt oxide family, the Nickle oxide family. the Neodymium oxide family, and the Iron oxide family.

4. The method as in claim 1, wherein the electrically insulating coating comprises silicon dioxide (SiO₂).

5. The method as in claim 1, wherein the base material comprises polymer, silicone, polyurethane, chloroprene, butyl, polybutadiene, neoprene, natural rubber, isoprene, resin, or epoxy.

6. The method as in claim 1, comprising dispersing a plurality of silicon dioxide (SiO₂) filler particles in the base material to form the mold structure.

7. The method as in claim 6, wherein dispersed particles comprise 50% to 95% shielding particles and 50% to 5% silicon dioxide filler particles.

8. The method as in claim 1, wherein positioning the mold structure proximate the die comprises the mold structure at least partially encapsulating the die.

9. The method as in claim 1, wherein positioning the mold structure proximate the die comprises comprising positioning first and second shielding layers, wherein the first and second shielding layers comprise different concentrations of the coated shielding particles.

10. A device comprising:
a die; and
a mold structure proximate the die, the mold structure comprising:
a base material; and
shielding particles comprising an electrically insulating coating, wherein the shielding particles are dispersed in the base material.

11. The device as in claim 10, wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO).

12. The device as in claim 10, wherein the shielding particles comprise a material from at least one of the Cobalt oxide family, the Nickle oxide family, the Neodymium oxide family, and the Iron oxide family.

13. The device as in claim 10, wherein the electrically insulating coating comprises silicon dioxide (SiO₂).

14. The device as in claim 10, wherein the base material comprises a material selected from polymer, silicone, polyurethane, chloroprene, butyl, polybutadiene, neoprene, natural rubber, isoprene, resin, and epoxy.

15. The device as in claim 10, wherein the mold structure comprises silicon dioxide (SiO₂) filler particles.

16. The device as in claim 15, wherein particles in the mold structure comprise 50% to 95% shielding particles and 50% to 5% silicon dioxide (SiO₂) filler particles.

17. The device as in claim 10, comprising an encapsulate at least partially encapsulating the die, wherein the mold structure is proximate the encapsulate.

18. The device as in claim 10, wherein the mold structure comprises first and second shielding layers, wherein the first and second shielding layers comprise different concentrations of shielding particles.

19. An system comprising:
a die carrier;
a die mounted on the die carrier; and
a mold structure proximate the die, the mold structure comprising:
a base material;
shielding particles comprising an electrically insulating coating, the shielding particles dispersed in the base material; and
silicon dioxide (SiO₂) filler particles dispersed in the base material.

20. The system as in claim 19,
wherein the shielding particles comprise at least one of boron nitride (BN), bismuth (Bi), bismuth oxide (Bi₂O₃), tantalum nitride (TaN), tungsten nitride (W₃N₂), tin oxide (SnO₂), copper (I) oxide (Cu₂O), or copper (II) oxide (CuO),
wherein the electrically insulating coating comprises silicon dioxide (SiO₂),
wherein the base material comprises polymer, silicone, polyurethane, chloroprene, butyl, polybutadiene, neoprene, natural rubber, isoprene, resin, or epoxy, and
wherein particles in the mold structure comprises 50% to 95% shielding particles and 50% to 5% silicon dioxide (SiO₂) filler particles.
